(19) United States
(12) Patent Application Publication
(10) Pub. No.: US 2015/0179880 A1
(43) Pub. Date: Jun. 25, 2015

(54) NITRIDE SEMICONDUCTOR STRUCTURE

(71) Applicant: Industrial Technology Research Institute, Hsinchu (TW)

(72) Inventors: Yen-Hsiang Fang, New Taipei City (TW); Rong Xuan, Hsinchu County (TW); Chia-Lung Tsai, Kaohsiung City (TW); Yu-Hsiang Chang, Hsinchu County (TW)

(73) Assignee: Industrial Technology Research Institute, Hsinchu (TW)

(21) Appl. No.: 14/139,880

(22) Filed: Dec. 24, 2013

(51) Int. Cl. H01L 33/14; H01L 33/32

(52) U.S. Cl. CPC H01L 33/14; H01L 33/325

(57) ABSTRACT

A nitride light emitting diode structure including a first type doped semiconductor layer, a second type doped semiconductor layer, a light emitting layer, a first metal pad, a second metal pad and a magnetic film is disclosed. The magnetic film disposed between the first metal pad and the first type doped semiconductor layer includes a zinc oxide (ZnO) layer doped with cobalt (Co). The content of Co in the ZnO layer ranges from 5% to 25% by molar ratio.

### BACKGROUND OF THE DISCLOSURE

1. Technical Field

The disclosure relates to a group III nitride semiconductor structure.

2. Background

Light emitting diodes (LEDs) nowadays are prevailing in commercial illumination. It is known that the external quantum efficiency (EQE) of the LED depends on the internal quantum efficiency (IQE) and the light extraction efficiency of the LED. However, the enhancement of the IQE has encountered the bottleneck since the key factor affecting IQE is the electron-hole pair recombination efficiency. Because the mobility of the electron is greater than the mobility of the hole and the electron overflow caused by the quantum confined Stark effect (QCSE), the electron-hole pair recombination efficiency is significantly reduced.

### SUMMARY

This disclosure provides a group III nitride LED structure having a magnetic film therein. The disclosure provides a nitride light emitting diode structure including a first type doped semiconductor layer, a second type doped semiconductor layer, a light emitting layer, two metal pads and a magnetic film under one of the two metal pads. Taking advantage of the magnetic film under the metal pad of the nitride LED structure, the mobility of the electrons is reduced before their entry into the quantum well layers as the electrons passing through the magnetic film are affected by the exchange coupling effect of the magnetic dipole moments among the magnetic film. Hence, by means of the magnetic film, the electronic overflow is alleviated, the electron-hole pair recombination efficiency and IQE of the nitride LED structure are enhanced, without changing the LED epitaxial structure.

The embodiment of the disclosure provides a nitride light emitting diode structure including a first type doped semiconductor layer, a second type doped semiconductor layer, a light emitting layer, a first metal pad, a second metal pad and a magnetic film. The second type doped semiconductor layer is disposed over the first type doped semiconductor layer, while the light emitting layer is disposed between the first type doped semiconductor layer and the second type doped semiconductor layer. The first metal pad is disposed on the first type doped semiconductor layer and electrically connected to the first type doped semiconductor layer. The second metal pad is disposed on the second type doped semiconductor layer and electrically connected to the second type doped semiconductor layer. The magnetic film disposed between the first metal pad and the first type doped semiconductor layer includes a cobalt doped (Co-doped) zinc oxide (ZnO) layer and the Co-doped ZnO layer has a content of oxygen (O) larger than 45% by molar ratio, and the cobalt (Co) in ZnO is ranging from 5% to 25% by molar ratio.

The embodiment of the disclosure provides a nitride light emitting diode structure including a first type doped semiconductor layer, a second type doped semiconductor layer, a light emitting layer, a first metal pad, a second metal pad and a magnetic film. The second type doped semiconductor layer is disposed over the first type doped semiconductor layer, while the light emitting layer is disposed between the first type doped semiconductor layer and the second type doped semiconductor layer. The first metal pad is disposed on the first type doped semiconductor layer and electrically connected to the first type doped semiconductor layer. The second metal pad is disposed on the second type doped semiconductor layer and electrically connected to the second type doped semiconductor layer. The magnetic film includes a cobalt doped (Co-doped) zinc oxide (ZnO) layer and the Co-doped ZnO layer has a content of oxygen (O) larger than 45% by molar ratio and a content of Co, relative to (Co+Zn), larger than 40% by molar ratio.

The embodiment of the disclosure provides a nitride light emitting diode structure including an n-type gallium nitride layer, a p-type gallium nitride layer, a light emitting layer, a first metal pad, a second metal pad and a magnetic film. The p-type gallium nitride layer is disposed over the n-type gallium nitride layer, while the light emitting layer is disposed between the n-type gallium nitride layer and the p-type gallium nitride layer. The first metal pad is disposed on the n-type gallium nitride layer and electrically connected to the n-type gallium nitride layer. The second metal pad is disposed on the p-type gallium nitride layer and electrically connected to the p-type gallium nitride layer. The magnetic film disposed between the first metal pad and the n-type gallium nitride layer includes a cobalt doped (Co-doped) zinc oxide (ZnO) layer. The nitride light emitting diode structure includes an undoped zinc oxide (ZnO) layer located between the magnetic film and the n-type gallium nitride layer.

A detailed description is given in the following embodiments with reference to the accompanying drawings.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view of a nitride light emitting diode structure according to an embodiment of the disclosure.

FIG. 2 is a schematic cross-sectional view of a nitride light emitting diode structure according to another embodiment of the disclosure.

FIG. 3 is a diagram showing the curve of the output power versus the operation current of a nitride semiconductor light emitting device with the magnetic film and without the magnetic film according to embodiments of the disclosure.

FIG. 4 is a diagram showing the curve of the external quantum efficiency (EQE) versus the operation current of a nitride semiconductor light emitting device with the magnetic film and without the magnetic film according to embodiments of the disclosure.

### DETAILED DESCRIPTION

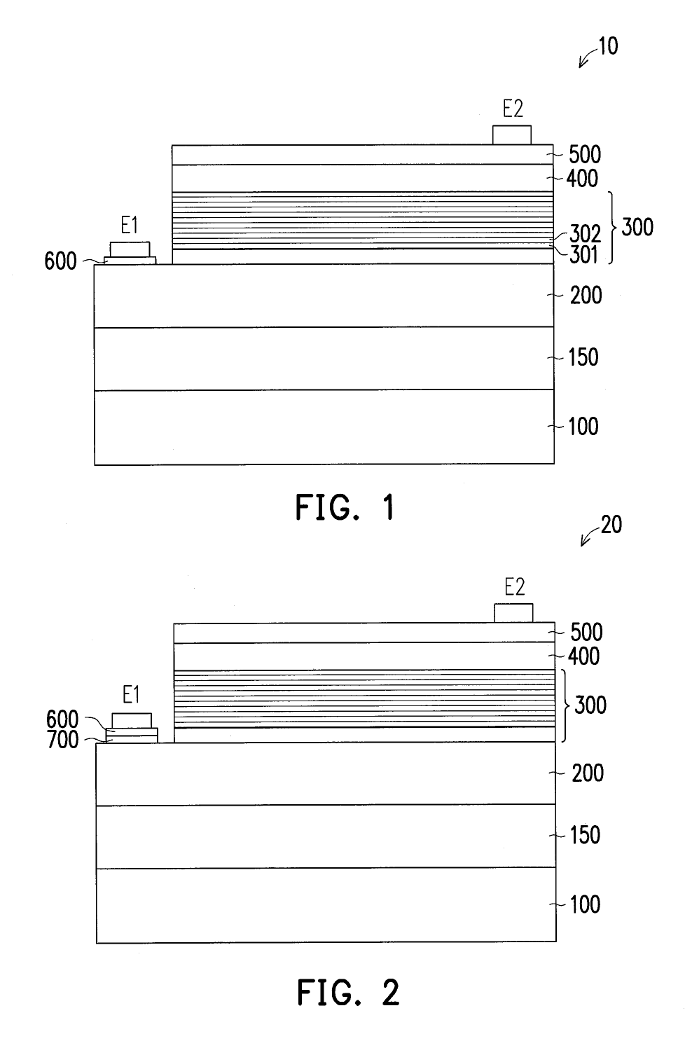

This disclosure provides a nitride light emitting diode (LED) structure. FIG. 1 is a cross-sectional view schematically showing a nitride LED structure according to an embodiment of the present disclosure. The LED element as described in this embodiment is a horizontal-type light emitting diode device. As shown in FIG. 1, the nitride LED structure 10 includes a mono crystalline substrate 100, a first type doped semiconductor layer 200, a light emitting layer 300, a second type doped semiconductor layer 400, a first electrode E1 and a second electrode E2. The first type doped semiconductor layer 200 is disposed over the monocrystalline substrate 100 with an undoped semiconductor layer 150 in-between. The light emitting layer 300 is disposed on the first type doped semiconductor layer 200 and the second type doped semiconductor layer 400 is disposed on the light emitting layer 300. The first electrode E1 and the second electrode E2 are respectively disposed on the first type doped semiconductor layer 200 and the second type doped semiconductor layer 400. In addition, for improving the poor contact between the electrode and the doped semiconductor material, a transparent conductive layer (TCL) 500 may be disposed between the second electrode E2 and the second type doped semiconductor layer 400. The transparent conductive layer 500 may be an indium tin oxide (ITO) layer, for example.

Specifically, the first type doped semiconductor layer 200 is, for example, an n-type nitride semiconductor layer, and the second type doped semiconductor layer 400 is, for example, a p-type nitride semiconductor layer.

In this embodiment as shown in FIG. 1, the light emitting layer 300 located between the first type doped semiconductor layer 200 and the second type doped semiconductor layer 400 may employ the multiple quantum well structure. That is, the multiple quantum well structure may be a laminated structure comprising a plurality of barrier layers 301 and a plurality of well layers 302, each with a thickness of several nanometers, arranged in alternation. For example, the barrier layers 301 may be GaN layers, and the well layers 302 may be InGaN layers. Alternatively, the barrier layers 301 may also be AlGaN layers and the well layers 302 may be InAlGaN layers, for example. The band gap is adjustable to enable the light emitting device to emit light of a blue light band. Alternatively, the light emitting layer 300 may be a single quantum well layer.

In FIG. 1, a portion of the transparent conductive layer 500, the second type doped semiconductor layer 400 and the light emitting layer 300 is etched down to expose a portion of the first type doped semiconductor layer 200. On the surface of the first type doped semiconductor layer 200 exposed by etching, the first electrode E1 is formed. The second electrode E2 is disposed at the same side (the upper side) of the LED structure as the first electrode E1. Hence, the nitride LED structure 10 is a horizontal LED structure. Taking the first type doped semiconductor layer 200 to be an n-type nitride semiconductor layer and the second type doped semiconductor layer 400 to be a p-type nitride semiconductor layer as an example, the first electrode E1 (n-pad) disposed on the n-type nitride semiconductor layer 200 is electrically connected to the n-type nitride semiconductor layer 200. The second electrode E2 (p-pad) disposed on the transparent conductive layer 500 is electrically connected to the p-type nitride semiconductor layer 400.

In FIG. 1, the nitride LED structure 10 further includes a magnetic film 600 between the first electrode E1 (n-pad) and the first type doped semiconductor layer 200. The magnetic film 600 may be a zinc oxide (ZnO) layer doped with cobalt (Co), for example. The zinc oxide (ZnO) layer doped with cobalt (Co), also denoted as the Co-doped ZnO layer or CoZnO layer. Preferably, the Co-doped ZnO layer has a thickness ranging from 100 nm to 500 nm, while the n-type nitride semiconductor layer has a thickness larger than or equivalent to 0.5 micron, for example. The content of O in Co-doped ZnO layer is larger than 45% by molar ratio, for example, and the content of Co in ZnO ranges from 5% to 25% by molar ratio. In addition, the content of Co in the CoZnO layer, relative to (Co+Zn), is larger than 40% by molar ratio, for example. The Co-doped ZnO layer may be formed by pulsed laser deposition (PLD) or co-sputtering, for example. The magnetic film 600 may also comprise a plurality of Co-doped ZnO layers. The area of the magnetic film 600 substantially equals to the area of the first electrode E1, for example. Alternatively, the area of the magnetic film 600 may be greater than the area of the first electrode E1.

FIG. 2 is a cross-sectional view schematically showing a nitride LED structure according to another embodiment of the present disclosure. In FIG. 2, the nitride LED structure 20 is similar to the nitride LED structure 10, except for having an additional ohmic contact layer 700 located between the magnetic film 600 and the first type doped semiconductor layer 200. The ohmic contact layer 700 may be an undoped zinc oxide (ZnO) layer having a thickness of 10 nm˜100 nm, preferably 60 nm, for example.

Taking advantage of the magnetic film of the nitride LED structure, the mobility of the electrons is significantly reduced before their entry into the quantum well structure as the electrons passing through the magnetic film are affected by the exchange coupling effect of the magnetic dipole moments among the magnetic film. Hence, by means of the magnetic film, the electronic overflow is alleviated, and the electron-hole pair recombination efficiency and IQE of the nitride LED structure are enhanced, without changing the LED epitaxial structure.

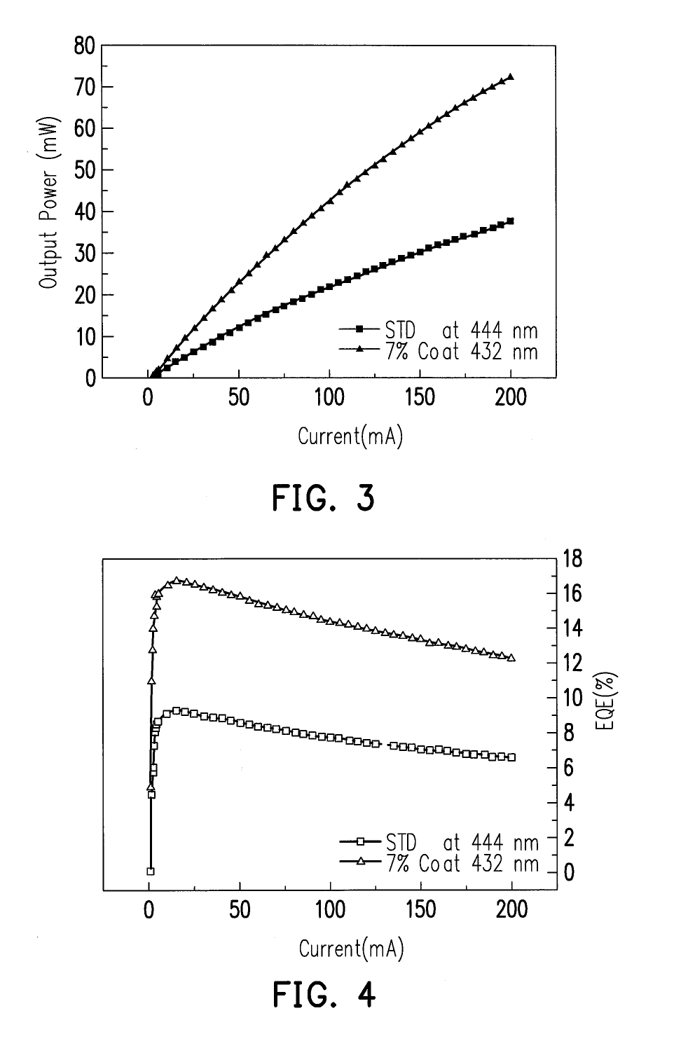

FIG. 3 is a diagram showing the curve of the output power versus the operation current of a nitride semiconductor light emitting device with the magnetic film and without the magnetic film. FIG. 4 is a diagram showing the curve of the external quantum efficiency (EQE) versus the operation current of a nitride semiconductor light emitting device with the magnetic film and without the magnetic film. In FIG. 3 or 4, the data denoted by “STD with 432 nm” corresponds to the data of the nitride light emitting device without the magnetic film and having peak emission at 432 nm (Sample “STD”). The data denoted by “7% Co at 444 nm” corresponds to the data of the nitride light emitting device with the magnetic film and having peak emission at 444 nm, while the magnetic film is made of Co doped ZnO, and the content of Co in ZnO is 7% by molar ratio (Sample “7% Co”) . As shown in the curves of FIG. 3, the output power of Sample “7% Co” is more than twice of the power of Sample “STD”. That is, the power of the nitride light emitting device with the magnetic film is increased more than 100% when compared with the nitride light emitting device without the magnetic film.

The “efficiency droop” or “droop effect”, the characteristic of GaN-based light-emitting diodes refers to the gradual decrease of efficiency as the injection-current density surpasses a low value typically between 0.1 and 10 A/cm². In FIG. 4, it is shown that the efficiency droop effects of these two curves similarly are about 27%. That is, the nitride light emitting device with the magnetic film has a higher optical power but has comparable luminescence efficiency when compared with the nitride light emitting device without the magnetic film.

The nitride LED structure similar to the structure of FIG. 1 is employed and Sample 1 refers to the sample having a ZnO layer on the exposed n-GaN layer and an n-pad on the ZnO layer. Sample 2 refers to the sample having no ZnO layer and having an n-pad on the exposed n-GaN layer. Sample 3 refers to the sample having a CoZnO layer on the exposed n-GaN layer and an n-pad on the CoZnO layer. Table 1 lists the carrier (electron) concentration and the mobility of the carriers (electrons) for the n-type GaN layer of Samples 1-3 obtained by Hall measurements.

TABLE 1

| | Concentration (cm⁻³) | Mobility (cm²/V-s) |
|---|---|---|
| Sample 1 | 4.16 * 10¹⁸ | 269 |
| Sample 2 | 4.18 * 10¹⁸ | 268 |
| Sample 3 | 5.77 * 10¹⁸ | 219 |

From the results of Table 1, it is found that the mobility of the electrons is not changed by having the ZnO layer on the n-type GaN layer, as the mobility of both Samples 1 and 2 are about the same. On the other hand, the mobility of the electrons is lowered by about 18% with the additional CoZnO layer on the n-type GaN layer, when compared the mobility of Samples 1 and 2. Further, the n-type doping concentration reaches 5.77*10¹⁸/cm³, which is larger than that of sample 1 and sample 2.

The following experiments are performed to compare the electrical properties of the nitride light emitting device with or without the magnetic film. As shown in the following Table 2, “STD” refers to the nitride light emitting device without the magnetic film, while “ZnOCo5%” or “ZnOCo7%” refers to the nitride light emitting device having the magnetic film made of Co doped ZnO and the content of Co in ZnO being 5% or 7% by molar ratio. From Table 2, the device(s) with the CoZnO layer, either the Co content in ZnO being 5% or 7%, is observed with a lower forward voltage

TABLE 2

| | Vf (20 mA) | Vf (100 mA) |
|---|---|---|
| STD | 3.62 | 4.78 |
| ZnOCo5% | 3.54 | 4.58 |
| ZnOCo7% | 3.36 | 4.49 |

* chip size: 800 μm × 400 μm; mesa height: 600 nm, Vf: forward voltage.

As shown in the following Table 3, “STD” refers to the nitride light emitting device without the magnetic film, while “ZnOCo17%” or “ZnOCo20%” refers to the nitride light emitting device having the magnetic film made of Co doped ZnO and the content of Co in ZnO being 17% or 20% by molar ratio. From Table 3, the device(s) with the CoZnO layer, either the Co content in ZnO being 17% or 20%, is observed with a lower forward voltage.

TABLE 3

| | Vf (20 mA) | Vf (100 mA) |
|---|---|---|
| STD | 3.36 | 4.28 |
| ZnOCo17% | 3.25 | 4.09 |
| ZnOCo20% | 3.22 | 4.01 |

* peak emission at 450 nm; chip size: 800 μm × 400 μm; mesa height: 600 nm, Vf: forward voltage.

As shown in the following Table 4, “STD” refers to the nitride light emitting device without the magnetic film, while “ZnOCo17%” or “ZnOCo20%” refers to the nitride light emitting device having the magnetic film made of Co doped ZnO and the content of Co in ZnO being 17% or 20% by molar ratio. From Table 4, the device(s) with the peak emission of 450 nm and having the CoZnO layer, either the Co content in ZnO being 17% or 20%, is observed with a lower forward voltage and a higher power. From Table 4, the device with the peak emission of 405 nm and having the CoZnO layer with the Co content in ZnO being 20%, is observed with a lower forward voltage and a higher power, while the device with the peak emission of 405 nm and having the CoZnO layer with the Co content in ZnO being 17%, is observed with a higher power.

TABLE 4

| Peak emission | | Vf (20 mA) | Vf (100 mA) | Power (mW) |
|---|---|---|---|---|
| 450 nm | STD | 3.36 | 4.28 | 14.73 |
| | ZnOCo17% | 3.25 | 4.09 | 16.62 |
| | ZnOCo20% | 3.22 | 4.01 | 19.15 |
| 405 nm | STD | 3.26 | 4.22 | 4.88 |
| | ZnOCo17% | 3.27 | 4.25 | 5.24 |
| | ZnOCo20% | 3.20 | 4.05 | 5.71 |

* chip size: 800 μm × 400 μm; mesa height: 600 nm, Vf: forward voltage.

Tables 2-4 list the forward voltage (Vf) of the nitride light emitting device (the structure of FIG. 1) under different operation currents (20 mA and 100 mA), and the obtained results of these samples are comparable Based on the data of Table 4, higher power and enhanced electrical properties are observed for the samples having the peak emission wavelength of 405 nm or 450 nm.

The following experiments are performed to compare the electrical properties of the nitride light emitting device with the magnetic film and further with the ZnO layer. As shown in the following Table 5, “ZnOCo17%” refers to the nitride light emitting device having the magnetic film made of Co doped ZnO and the content of Co in ZnO being 17% by molar ratio. “ZnO/ZnOCo17%” refers to the nitride light emitting device having an undoped ZnO layer and the magnetic film made of Co doped ZnO and the content of Co in ZnO being 17% by molar ratio. From Table 5, the device of ZnO/ZnOCo17% is observed with a lower forward voltage and a lower N—N resistance.

TABLE 5

| | | | | N—N resistance | |
|---|---|---|---|---|---|
| | Vf | Vf | Leakage | (mΩ) | |
| | (20 mA) | (100 mA) | (1 μA) | 20 mA | 100 mA |
| ZnOCo17% | 3.48 | 4.58 | 2.13 | 0.027 | 0.0268 |
| ZnO/ZnOCo17% | 3.28 | 4.37 | 2.14 | 0.0185 | 0.0169 |

In Table 6, “STD” refers to the nitride LED structure similar to the structure of FIG. 1 but without CoZnO layer. Sample 5 uses the nitride LED structure similar to the structure of FIG. 1, and the CoZnO layer has the content of O smaller than 45% by molar ratio (O<45%) and the content of Co in the CoZnO layer, relative to (Co+Zn), smaller than 40% by molar ratio. Sample 6 uses the nitride LED structure similar to the structure of FIG. 1, and the CoZnO layer has the content of O larger than 45% by molar ratio (O>45%) and the content of Co in the CoZnO layer, relative to (Co+Zn), larger than 40% by molar ratio. From Table 6, Sample 6, having the CoZnO layer of O>45% and the Co content in the CoZnO layer relative to (Co+Zn) larger than 40%, is observed with a much higher power, when compared with Sample 5. This indicates that the content of O larger than 45% by molar ratio (O>45%) in the CoZnO layer is important.

TABLE 6

| Sample | Power (mW) |
|---|---|
| STD | 36.54 |
| Sample 5 | 38.61 |
| Sample 6 | 44.87 |

The magnetic film may impose magnetic coupling to the electrons through the exchange coupling effect of the magnetic dipole moments among the magnetic film so that the electrons passing through the magnetic film are delayed and the mobility of the electrons is significantly reduced before their entry into the quantum wells. Hence, with the magnetic film formed under the electrode, the electronic overflow is alleviated, the electron-hole pair recombination efficiency and IQE of the nitride LED structure are enhanced, without significantly changing the LED epitaxial structure.

Meanwhile, as the fabrication of the nitride light emitting diode structure of this disclosure is compatible with the common epitaxial semiconductor manufacturing processes, the luminescence efficiency of the nitride light emitting diode structure of this disclosure is enhanced without increasing the production costs.

This disclosure has been described above in several embodiments, but is not limited to those. It is known to persons skilled in the art that some modifications and innovations may be made without departing from the spirit and scope of this disclosure. Hence, the scope of this disclosure can be defined by the following claims.

What is claimed is:

1. A nitride light emitting diode structure, comprising:
a first type doped semiconductor layer;
a second type doped semiconductor layer, disposed over the first type doped semiconductor layer;
a light emitting layer, disposed between the first type doped semiconductor layer and the second type doped semiconductor layer;
a first metal pad, disposed on the first type doped semiconductor layer and electrically connected to the first type doped semiconductor layer;
a second metal pad, disposed on the second type doped semiconductor layer and electrically connected to the second type doped semiconductor layer; and
a magnetic film disposed between the first metal pad and the first type doped semiconductor layer, wherein the magnetic film includes a cobalt doped (Co-doped) zinc oxide (ZnO) layer and the Co-doped ZnO layer has a content of oxygen (O) larger than 45% by molar ratio, and the cobalt (Co) in ZnO ranges from 5% to 25% by molar ratio.

2. The nitride light emitting diode structure of claim 1, wherein the Co-doped ZnO layer has a content of Co, relative to (Co+Zn), larger than 40% by molar ratio.

3. The nitride light emitting diode structure of claim 2, wherein the magnetic film has a thickness ranging from 100 nm to 500 nm.

4. The nitride light emitting diode structure of claim 1, further comprising an ohmic contact layer located between the magnetic film and the first type doped semiconductor layer.

5. The nitride light emitting diode structure of claim 4, wherein the ohmic contact layer is an undoped zinc oxide (ZnO) layer having a thickness of 10 nm˜100 nm.

6. A nitride light emitting diode structure, comprising:
a first type doped semiconductor layer;
a second type doped semiconductor layer, disposed over the first type doped semiconductor layer;
a light emitting layer, disposed between the first type doped semiconductor layer and the second type doped semiconductor layer;
a first metal pad, disposed on the first type doped semiconductor layer and electrically connected to the first type doped semiconductor layer;
a second metal pad, disposed on the second type doped semiconductor layer and electrically connected to the second type doped semiconductor layer; and
a magnetic film disposed between the first metal pad and the first type doped semiconductor layer, wherein the magnetic film includes a cobalt doped (Co-doped) zinc oxide (ZnO) layer and the Co-doped ZnO layer has a content of oxygen (O) larger than 45% by molar ratio and a content of Co, relative to (Co+Zn), larger than 40% by molar ratio.

7. The nitride light emitting diode structure of claim 6, wherein the cobalt (Co) in ZnO ranges from 5% to 25% by molar ratio for the Co-doped ZnO layer.

8. The nitride light emitting diode structure of claim 6, wherein the magnetic film has a thickness ranging from 100 nm to 500 nm.

9. The nitride light emitting diode structure of claim 6, further comprising an ohmic contact layer located between the magnetic film and the first type doped semiconductor layer.

10. The nitride light emitting diode structure of claim 9, wherein the ohmic contact layer is an undoped zinc oxide (ZnO) layer having a thickness of 10 nm˜100 nm.

11. A nitride light emitting diode structure, comprising:
an n-type gallium nitride layer;
a p-type gallium nitride layer, disposed over the n-type gallium nitride layer;
a light emitting layer, disposed between the n-type gallium nitride layer and the p-type gallium nitride layer;
a first metal pad, disposed on and electrically connected to the n-type gallium nitride layer;
a second metal pad, disposed on and electrically connected to the p-type gallium nitride layer;
a magnetic film disposed between the first metal pad and the n-type gallium nitride layer, wherein the magnetic film includes a cobalt doped (Co-doped) zinc oxide (ZnO) layer; and
an undoped zinc oxide (ZnO) layer located between the magnetic film and the n-type gallium nitride layer.

12. The nitride light emitting diode structure of claim 11, wherein the Co-doped ZnO layer has a content of oxygen (O) larger than 45%.

13. The nitride light emitting diode structure of claim 11, wherein the Co-doped ZnO layer has a content of Co, relative to (Co+Zn), larger than 40% by molar ratio.

14. The nitride light emitting diode structure of claim 11, wherein the cobalt (Co) in ZnO ranges from 5% to 25% by molar ratio for the Co-doped ZnO layer.

15. The nitride light emitting diode structure of claim 11, wherein the n-type gallium nitride layer has a thickness larger than or equivalent to 0.5 micron.

16. The nitride light emitting diode structure of claim 11, the undoped ZnO layer having a thickness of 10 nm˜100 nm.

17. The nitride light emitting diode structure of claim 11, wherein the magnetic film has a thickness ranging from 100 nm to 500 nm.
